(19) United States
(12) Patent Application Publication
(10) Pub. No.: US 2026/0281521 A1
(43) Pub. Date: Sep. 17, 2026

(54) IMAGING DEVICE, IMAGING SYSTEM, AND IMAGING METHOD

(71) Applicant: Panasonic Intellectual Property Management Co., Ltd., Osaka (JP)

(72) Inventors: SATOSHI SATO, Kyoto (JP); MOTOKI YAKO, Osaka (JP); KUNIO NOBORI, Osaka (JP)

(21) Appl. No.: 19/676,905

(22) Filed: May 14, 2026

Related U.S. Application Data
(63) Continuation of application No. PCT/JP2025/007035, filed on Feb. 28, 2025.

(30) Foreign Application Priority Data
Mar. 12, 2024 (JP) 2024-038379

(51) Int. Cl. H04N 23/11; H04N 23/54; H04N 23/55; H04N 23/62; H04N 23/667

(52) U.S. Cl. CPC H04N 23/11; H04N 23/54; H04N 23/55; H04N 23/62; H04N 23/667

(57) ABSTRACT

An imaging device includes an optical filter including regions having different transmittance spectra from each other, an optical element, and an image sensor that detects light through the optical element and the optical filter to generate a compressed image in which information regarding four or more wavelength bands is compressed. The optical element reduces a spatial frequency component of light incident on the optical element that is greater than or equal to a specific frequency, and the specific frequency is less than or equal to 1/(5P) when a pixel pitch of the image sensor is P.

### BACKGROUND

### 1. Technical Field

The present disclosure relates to an imaging device, an imaging system, and an imaging method.

### 2. Description of the Related Art

Compressed sensing is a technique that reconstructs more data than observed data by assuming that the distribution of observation target data is sparse in a certain space, such as frequency space. Compressed sensing can be applied, for example, to an imaging device that reconstructs an image including more information from a small amount of observation data. An imaging device to which compressed sensing is applied generates reconstructed images through arithmetic operations from an image in which the spectral information of a target has been compressed. As a result, various effects on images can be obtained such as higher resolution, wavelength expansion, shorter imaging time, or higher sensitivity.

U.S. Pat. No. 9,599,511 discloses an example of applying compressed sensing technology to a hyperspectral camera that acquires images in wavelength bands, each having a narrow bandwidth. According to the technology disclosed in U.S. Pat. No. 9,599,511, it is possible to realize a hyperspectral camera that generates high-resolution and multi-wavelength images.

### SUMMARY

One non-limiting and exemplary embodiment provides an imaging device capable of reducing the reconstruction error of a reconstructed image when generating the reconstructed image on the basis of an image in which spectral information is compressed.

In one general aspect, the techniques disclosed here feature an imaging device including: an optical filter including regions having different transmittance spectra from each other, an optical element, and an image sensor that detects light through the optical element and the optical filter to generate a compressed image in which information regarding four or more wavelength bands is compressed. The optical element reduces a spatial frequency component of light incident on the optical element that is greater than or equal to a specific frequency, and the specific frequency is less than or equal to 1/(5P) when a pixel pitch of the image sensor is P.

According to the technology of the present disclosure, an imaging device can be realized that is capable of reducing the reconstruction error of a reconstructed image when generating the reconstructed image on the basis of an image in which spectral information is compressed.

General or specific embodiments of the present disclosure may be implemented as a system, an apparatus, a method, an integrated circuit, a computer program, a computer-readable recording medium, such as a recording disc, or any selective combination thereof. Examples of the computer-readable recording medium include a nonvolatile recording medium such as a compact disc read-only memory (CD-ROM). The apparatus may be formed by one or more devices. In a case where the apparatus is formed by two or more devices, the two or more devices may be disposed in a single apparatus or may be distributed among two or more separate apparatuses. In this specification and the claims, an “apparatus” may refer not only to a single apparatus but also to a system formed by apparatuses.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a diagram schematically illustrating an example of the configuration of an imaging system;

FIG. 1B is a diagram schematically illustrating another example of the configuration of the imaging system;

FIG. 1C is a diagram schematically illustrating yet another example of the configuration of the imaging system;

FIG. 1D is a diagram schematically illustrating yet another example of the configuration of the imaging system;

FIG. 2A is a diagram schematically illustrating an example of a filter array;

FIG. 2B includes diagrams illustrating an example of a spatial distribution of optical transmittance of each of wavelength bands W₁, W₂, . . . , W_{N} included in a target wavelength range;

FIG. 2C is a diagram illustrating an example of the spectral transmittance of a region A1 included in the filter array illustrated in FIG. 2A;

FIG. 2D is a diagram illustrating an example of the spectral transmittance of a region A2 included in the filter array illustrated in FIG. 2A;

FIG. 3 is a diagram for describing the relationship between a target wavelength range W and wavelength bands W₁, W₂, . . . , W_{N} included in the target wavelength range W;

FIG. 4A is a diagram for describing characteristics of the spectral transmittance of a certain region of the filter array;

FIG. 4B is a diagram illustrating a result obtained by averaging, on a wavelength band basis, the spectral transmittance of each of the wavelength bands W₁, W₂, . . . , W_{N} illustrated in FIG. 4A;

FIG. 5A is a diagram schematically illustrating a configuration example 1 of an imaging system according to the present embodiment that reduces the reconstruction error of a reconstructed image;

FIG. 5B is a diagram schematically illustrating a configuration example 2 of the imaging system according to the present embodiment that reduces the reconstruction error of a reconstructed image;

FIG. 5C is a diagram schematically illustrating a configuration example 3 of the imaging system according to the present embodiment that reduces the reconstruction error of a reconstructed image;

FIG. 5D is a diagram schematically illustrating a configuration example 4 of the imaging system according to the present embodiment that reduces the reconstruction error of a reconstructed image;

FIG. 5E is a diagram schematically illustrating a configuration example 5 of the imaging system according to the present embodiment that reduces the reconstruction error of a reconstructed image;

FIG. 5F is a diagram schematically illustrating a configuration example 6 of the imaging system according to the present embodiment that reduces the reconstruction error of a reconstructed images;

FIG. 5G is a diagram schematically illustrating a configuration example 7 of the imaging system according to the present embodiment that reduces the reconstruction error of a reconstructed image;

FIG. 5H is a diagram schematically illustrating a configuration example 8 of the imaging system according to the present embodiment that reduces the reconstruction error of a reconstructed image;

FIG. 6 is a graph illustrating the transmission spectra of low-pass filters used in an imaging device according to the present embodiment and existing cameras;

FIG. 7 is a graph illustrating the reconstruction error of a reconstructed image of a target including a color chart when red, green, and blue regions are extracted from a compressed image while varying the number of pixels in each of the red, green, and blue regions;

FIG. 8 is a diagram schematically illustrating another configuration example of the imaging system according to the present embodiment that reduces the reconstruction error of a reconstructed image;

FIG. 9 is a diagram schematically illustrating yet another configuration example of the imaging system according to the present embodiment that reduces the reconstruction error of a reconstructed image;

FIG. 10 is a flowchart schematically illustrating Example 1 of a processing operation performed by a processing circuit;

FIG. 11 is a flowchart schematically illustrating Example 2 of the processing operation performed by the processing circuit;

FIG. 12 is a flowchart schematically illustrating Example 3 of the processing operation performed by the processing circuit;

FIG. 13 is a flowchart schematically illustrating Example 4 of the processing operation performed by the processing circuit;

FIG. 14A is a diagram schematically illustrating Example 1 of a user interface (UI) displayed on a display device in a spectral display mode;

FIG. 14B is a diagram schematically illustrating Example 2 of the UI displayed on the display device in the spectral display mode;

FIG. 14C is a diagram schematically illustrating Example 3 of the UI displayed on the display device in the spectral display mode;

FIG. 14D is a diagram schematically illustrating Example 4 of the UI displayed on the display device in the spectral display mode;

FIG. 14E is a diagram schematically illustrating Example 5 of the UI displayed on the display device in the spectral display mode; and

FIG. 14F is a diagram schematically illustrating a UI example displayed on the display device in a through-display mode.

### DETAILED DESCRIPTIONS

In the present disclosure, all or one or more of circuits, units, devices, members, or portions or all or one or more of the functional blocks of a block diagram may be executed by, for example, one or more electronic circuits including a semiconductor device, a semiconductor integrated circuit (IC), or a large-scale integration circuit (LSI). The LSI or the IC may be integrated on one chip or may be formed by combining chips. For example, functional blocks other than a storage device may be integrated on one chip. In this case, the term LSI or IC is used; however, the term(s) to be used may change depending on the degree of integration, and the term such as system LSI, very large-scale integration (VLSI), or ultra-large-scale integration (ULSI) may be used. A field-programmable gate array (FPGA) or a reconfigurable logic device that allows reconfiguration of interconnection inside the LSI or setup of a circuit section inside the LSI can also be used for the same purpose, the FPGA and the reconfigurable logic device being programmed after the LSI is manufactured.

Furthermore, functions or operations of all or one or more of the circuits, the units, the devices, the members, or the portions can be executed through software processing. In this case, the software is recorded in one or more non-transitory recording media, such as a read-only memory (ROM), an optical disc, or a hard disk drive, and when the software is executed by a processing device (a processor), the function specified by the software is executed by the processing device (the processor) and its peripheral devices. The system or the apparatus may include the one or more non-transitory recording media in which the software is recorded, the processing device (the processor), and a hardware device to be needed, such as an interface.

In the present disclosure, “light” refers not only to visible light (wavelengths from about 400 nm to about 700 nm) but also to electromagnetic waves including ultraviolet rays (wavelengths from about 10 nm to about 400 nm) and infrared rays (wavelengths from about 700 nm to about 1 mm).

In the following, examples of embodiments of the present disclosure will be described. Note that any one of the embodiments to be described below is intended to represent a general or specific example. The numerical values, shapes, constituent elements, arrangement positions and connection forms of the constituent elements, steps, and the order of steps are examples and are not intended to limit the present disclosure. Among the constituent elements of the following embodiments, the constituent elements that are not described in independent claims representing the most generic concept will be described as optional constituent elements. Each diagram is a schematic diagram and is not necessarily precisely illustrated. Furthermore, in each diagram, substantially the same or similar constituent elements are denoted by the same reference signs. Redundant description may be omitted or simplified.

Before describing the embodiments of the present disclosure, the findings underlying the present disclosure will be described.

The process of classifying targets in an image by type in the field of imaging is used in fields such as factory automation (FA) and medicine. Examples of features used in the classification process include spectral information regarding the targets as well as the shapes of the targets. Since hyperspectral cameras can acquire multi-wavelength images that contain abundant spectral information per pixel, it is expected that hyperspectral cameras will be utilized in the future. While research and development of hyperspectral cameras has been conducted worldwide for many years, their use has been limited for the following reasons. For example, line-scan hyperspectral cameras provide high spatial and wavelength resolution but take longer to capture images due to line scanning. Snapshot hyperspectral cameras can capture images in a single shot but often lack sufficient sensitivity and spatial resolution.

In contrast to them, it has recently been reported that the sensitivity and spatial resolution of hyperspectral cameras can be improved by reconstructing images on the basis of sparsity. Sparsity is the property that the elements characterizing an observation target are present in a certain space, such as frequency space, in a sparse manner. Sparsity is widely observed in the natural world. The use of sparsity makes it possible to efficiently observe necessary information. Sparsity-based sensing technology is called compressed sensing technology. Compressed sensing technology can be used to construct highly efficient devices and systems.

As a specific application example of compressed sensing technology, a hyperspectral camera with improved wavelength resolution has been proposed, as disclosed in U.S. Pat. No. 9,599,511, for example. Such a hyperspectral camera is equipped, for example, with an optical filter that has irregular optical transmission characteristics with respect to space, wavelength, or both. Such an optical filter is also referred to as an “encoding mask”. An encoding mask is disposed along an optical path of light incident on an image sensor and transmits the incident light from a target so as to have region-dependent optical transmission characteristics. This process performed by the encoding mask is referred to as “encoding”. The spectral information regarding the target is compressed in an image of the target acquired through the encoding mask. The image is referred to as a “compressed image”. Mask information indicating the optical transmittance of the encoding mask is stored in advance as a reconstruction table in a memory device.

An image processing apparatus performs a reconstruction process on the basis of the compressed image and the reconstruction table. The reconstruction process makes it possible to obtain more information than the compressed image has. Examples of the information include higher resolution image information, image information covering more wavelengths, or both. The reconstruction table may be, for example, data indicating the spatial distribution of the optical response characteristics of the encoding mask. The reconstruction process based on such a reconstruction table makes it possible to generate reconstructed images, which correspond to the respective wavelength bands included in a target wavelength range, from a single compressed image. In the following description, “reconstructed images” are also simply referred to as “reconstructed images”.

In compressed sensing technology, in a case where a compressed image is not suitable for the reconstruction process, the reconstruction error of a reconstructed image increases. The reconstruction error corresponds to the difference between the reconstructed image of a subject obtained through the reconstruction process and the correct (ground truth) image of the subject, as described below. An example of the compressed image that is not suitable for the reconstruction process is that the target contains a fine structure. This is because the size of the fine structure is not sufficiently large relative to the pixel pitch in the correct image in which the target appears and the condition for the regularization term described below is not satisfied. More specifically, the reason is as follows. In a case where total variation (TV) is used as the stabilization term, it is assumed that the change in the luminance of the correct image is small. However, in a case where the target contains a fine structure, the change in the luminance of the correct image increases, and the assumption that “the change in the luminance of the correct image is small” in the reconstruction process is no longer satisfied, resulting in an increase in reconstruction error.

The present inventors found a problem in that the reconstruction error increases in a case where a target contains a fine structure, and arrived at imaging devices and imaging systems according to the embodiments of the present disclosure that can solve the problem. An imaging device according to the present embodiment reduces a high spatial frequency component of the light from a target that is incident on the image sensor by using a low-pass filter or by vibrating the image sensor. An imaging system according to the present embodiment reduces a high spatial frequency component of the light from a target that is incident on the image sensor by adjusting the focus position of the optical system so that the optical system is out of focus. As a result, when generating reconstructed images on the basis of a compressed image generated by the image sensor, since the reconstructed images are generated while satisfying the assumption that “the change in the luminance of the correct image is small”, the imaging device and the imaging system according to the present embodiment can reduce the reconstruction errors of the reconstructed images.

### Embodiments

In the following, first, an imaging system that generates reconstructed images on the basis of compressed images will be described. Next, a method for reducing reconstruction errors of reconstructed images even in a case where a target contains a fine structure will be described.

### 1. Imaging System

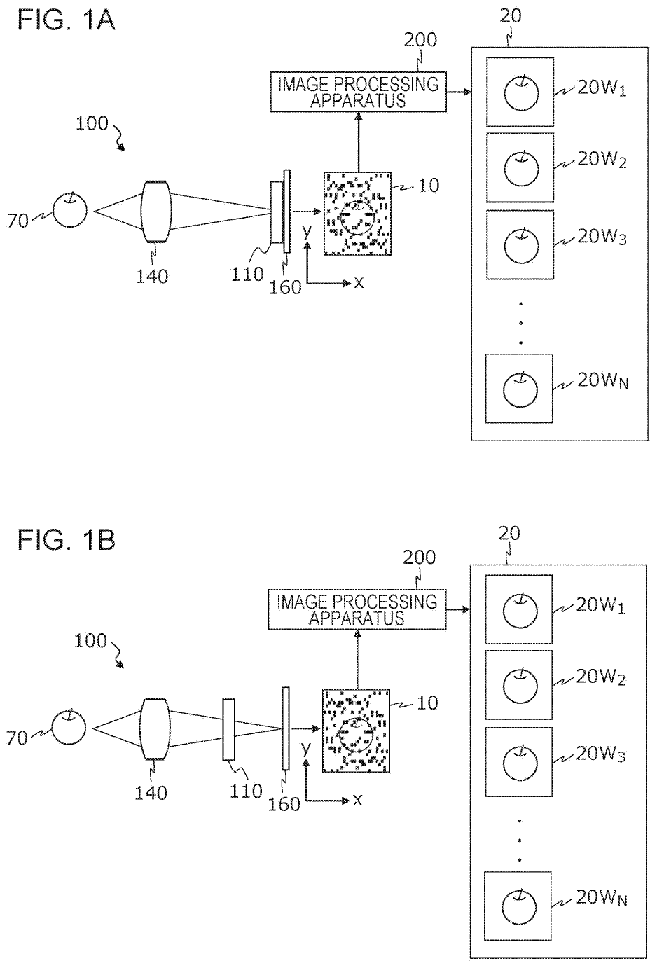

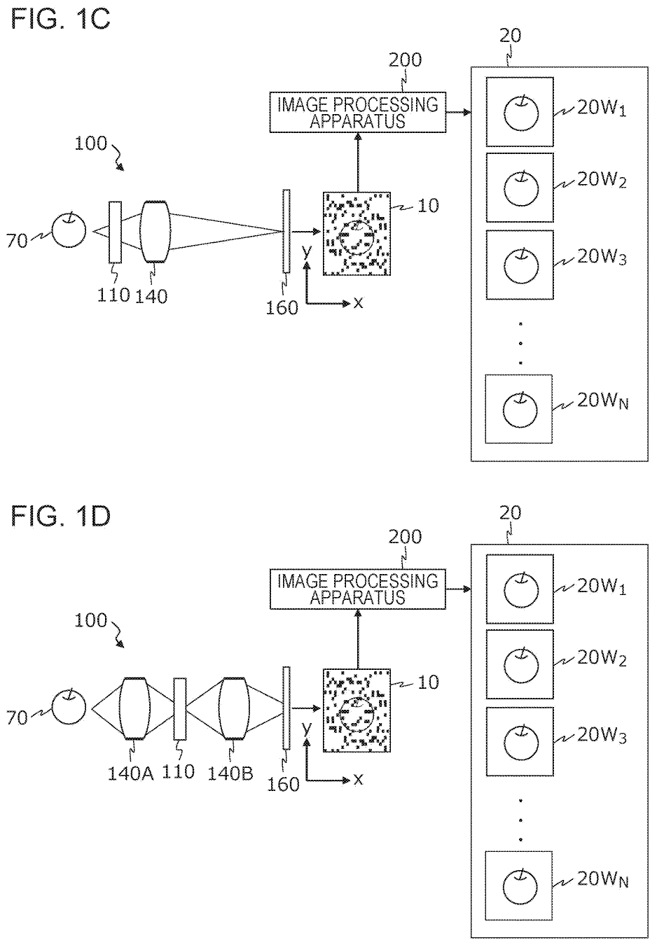

FIG. 1A is a diagram schematically illustrating an example of the configuration of an imaging system. The system illustrated in FIG. 1A includes an imaging device 100 and an image processing apparatus 200. The imaging device 100 has substantially the same configuration as the imaging device disclosed in U.S. Pat. No. 9,599,511. The imaging device 100 includes an optical system 140, a filter array 110, and an image sensor 160. The optical system 140 and the filter array 110 are disposed along an optical path of incident light from a target 70, which is a subject. The filter array 110 in the example illustrated in FIG. 1A is disposed between the optical system 140 and the image sensor 160.

FIG. 1A illustrates an apple as an example of the target 70. The target 70 is not limited to an apple, and may be any object. The image sensor 160 generates data of a compressed image 10, which is obtained by compressing information regarding wavelength bands into a two-dimensional monochrome image. The image processing apparatus 200 generates data representing images that correspond one-to-one to wavelength bands included in a predetermined target wavelength range, on the basis of the data of the compressed image 10 generated by the image sensor 160. In this case, suppose that the number of wavelength bands included in the target wavelength range is N (N is an integer greater than or equal to 4). In the following description, N images generated on the basis of the compressed image 10 are referred to as reconstructed images 20W₁, 20W₂, . . . , 20W_{N}, and these images may also be referred to collectively as a “hyperspectral image 20”.

The filter array 110 in the present embodiment is an array of filters arranged in rows and columns and having translucency. The filters include different kinds of filters having different spectral transmittances from each other, that is, having different wavelength-dependent optical transmittances from each other. The filter array 110 modulates the intensity of incident light for each wavelength and outputs the resulting light. This process performed by the filter array 110 will be referred to as “encoding”, and the filter array 110 will be also referred to as an “encoding mask”. Alternatively, the filter array 110 is also simply referred to as an “optical filter”.

In the example illustrated in FIG. 1A, the filter array 110 is disposed near or directly on the image sensor 160. In this case, “near” refers to the filter array 110 being close enough to the image sensor 160 that an image of light from the optical system 140 is formed on the surface of the filter array 110 in a state where the image of light has a certain degree of clearness. “Directly on” refers to the filter array 110 and the image sensor 160 being close to each other to an extent that there is hardly any gap therebetween. The filter array 110 and the image sensor 160 may be formed as a single device.

The optical system 140 includes at least one lens. In FIG. 1A, the optical system 140 is illustrated as one lens; however, the optical system 140 may be a combination of lenses. The optical system 140 forms an image on an imaging surface of the image sensor 160 through the filter array 110.

The filter array 110 may be disposed so as to be spaced apart from the image sensor 160. FIGS. 1B to 1D are diagrams illustrating examples of the configuration of the imaging device 100, in which the filter array 110 is arranged so as to be spaced apart from the image sensor 160. In the example illustrated in FIG. 1B, the filter array 110 is disposed between the optical system 140 and the image sensor 160 and at a position spaced apart from the image sensor 160. In the example illustrated in FIG. 1C, the filter array 110 is disposed between the target 70 and the optical system 140. In the example illustrated in FIG. 1D, the imaging device 100 includes two optical systems 140A and 140B, and the filter array 110 is disposed between the optical systems 140A and 140B. As in these examples, an optical system including one or more lenses may be disposed between the filter array 110 and the image sensor 160.

The image sensor 160 is a monochrome light detector having light detection devices (also referred to as “pixels” in this specification) arranged two-dimensionally. The image sensor 160 may be, for example, a charge-coupled device (CCD), a complementary metal oxide semiconductor (CMOS) sensor, or an infrared array sensor. The light detection devices include, for example, a photodiode. The image sensor 160 is not necessarily a monochrome sensor. For example, color sensors may be used. A color sensor may include, for example, red (R) filters transmitting red light, green (G) filters transmitting green light, and blue (B) filters transmitting blue light. The color sensor may further include IR filters that transmit infrared light. Moreover, the color sensor may include transparent filters that transmit all of the red, green, and blue light. The use of the color sensor can increase the amount of information regarding wavelengths and improve the reconstruction accuracy of the hyperspectral image 20. A wavelength range as an acquisition target may be freely determined. The wavelength range is not limited to the visible wavelength range and may also be the ultraviolet wavelength range, the near infrared wavelength range, the mid-infrared wavelength range, or the far-infrared wavelength range.

The image processing apparatus 200 may be a computer including one or more processors and one or more storage media, such as a memory. The image processing apparatus 200 generates data of reconstructed images 20W₁, 20W₂, . . . , 20W_{N} on the basis of the compressed image 10 acquired by the image sensor 160.

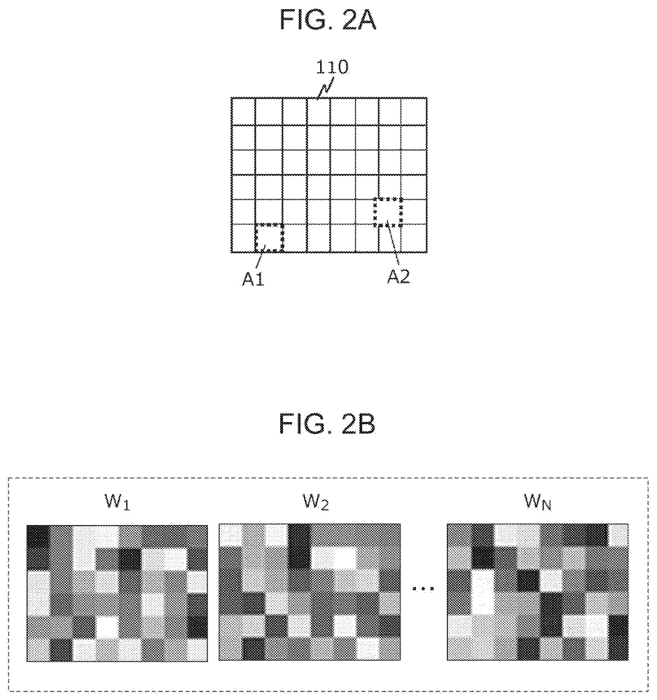

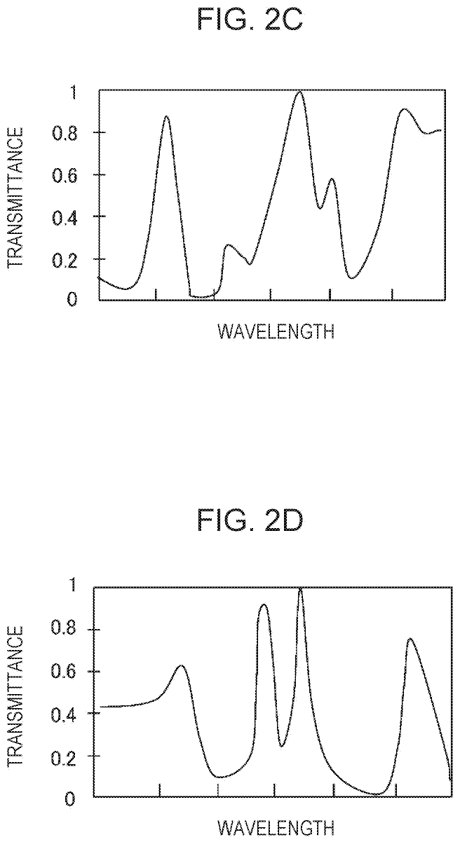

FIG. 2A is a diagram schematically illustrating an example of the filter array 110. The filter array 110 has regions arranged two-dimensionally. In this specification, these regions may be referred to as “cells”. In each region, a filter having a spectral transmittance set individually is disposed. Spectral transmittance is expressed by a function T(λ), where the wavelength of incident light is λ. The spectral transmittance T(λ) may have a value greater than or equal to 0 and less than or equal to 1.

In the example illustrated in FIG. 2A, the filter array 110 has 48 rectangular regions arranged in 6 rows and 8 columns. This is merely an example, and a larger number of regions than this may be provided in actual applications. The number of regions may be about the same as, for example, the number of pixels of the image sensor 160. The number of filters included in the filter array 110 is determined in accordance with the application, for example, within a range from several tens to several tens of millions.

FIG. 2B includes diagrams illustrating an example of a spatial distribution of optical transmittance of each of wavelength bands W₁, W₂, . . . , W_{N} included in the target wavelength range. In the example illustrated in FIG. 2B, differences in shading between the regions represent differences in transmittance. The lighter the shade of the region, the higher the transmittance. The darker the shade of the region, the lower the transmittance. As illustrated in FIG. 2B, the spatial distribution of optical transmittance differs depending on the wavelength band.

FIG. 2C is a diagram illustrating an example of the spectral transmittance of a region A1, and FIG. 2D is a diagram illustrating an example of the spectral transmittance of a region A2, the regions A1 and A2 being included in the filter array 110 illustrated in FIG. 2A. The spectral transmittance of the region A1 is different from that of the region A2. In this manner, the spectral transmittance of the filter array 110 varies depending on the region. Note that all the regions do not necessarily have different spectral transmittances from each other. At least some of the regions included in the filter array 110 have different spectral transmittances from each other. The filter array 110 includes two or more filters that have different spectral transmittances from each other. In one example, the number of patterns of spectral transmittances of the regions included in the filter array 110 may be the same as N, which is the number of wavelength bands included in the target wavelength range, or greater than or equal to N. The filter array 110 may be designed such that at least half of the regions have different spectral transmittances from each other.

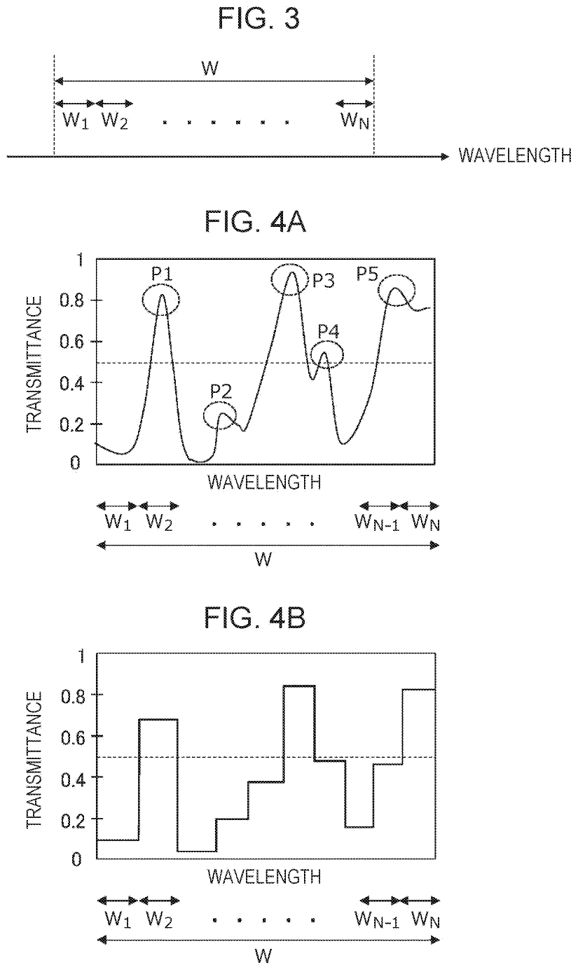

FIG. 3 is a diagram for describing the relationship between a target wavelength range W and wavelength bands W₁, W₂, . . . , W_{N} included in the target wavelength range W. The target wavelength range W may be set to various ranges depending on the application. The target wavelength range W may have, for example, a wavelength range of visible light of about 400 nm to about 700 nm, a wavelength range of near infrared rays of about 700 nm to about 2500 nm, or a wavelength range of near ultraviolet rays of about 10 nm to about 400 nm. Alternatively, the target wavelength range W may be a wavelength range of mid-infrared rays or a wavelength range of far-infrared rays. In this manner, the wavelength range to be used is not limited to the visible light range. In this specification, not only visible light but also radiation in general including infrared rays and ultraviolet rays will be referred to as “light”.

In the example illustrated in FIG. 3, N is set to any integer greater than or equal to 4, the target wavelength range W is equally divided into N sections, and the N wavelength ranges are referred to as the wavelength bands W₁, W₂, . . . , W_{N}. Note that the example is not limited to this one. The wavelength bands included in the target wavelength range W may be freely set. For example, the wavelength bands may have different bandwidths.

FIG. 4A is a diagram for describing characteristics of the spectral transmittance of a certain region of the filter array 110. In the example illustrated in FIG. 4A, regarding wavelengths within the target wavelength range W, the spectral transmittance has local maxima P1 to P5 and local minima. In the example illustrated in FIG. 4A, the spectral transmittance has local maxima in the wavelength ranges of, for example, the wavelength band W₂ and the wavelength band W_{N-1}. In this manner, the spectral transmittance of each region may be designed to have local maxima in at least two of the wavelength ranges of the wavelength bands W₁, W₂, . . . , W_{N}. In the example illustrated in FIG. 4A, the local maxima P1, P3, P4, and P5 are greater than or equal to 0.5.

In this manner, the optical transmittance of each region varies with wavelength. Thus, the filter array 110 transmits a large amount of a certain wavelength range component of incident light but does not substantially transmit other wavelength range components of the incident light. For example, the transmittances of light in k wavelength bands among the N wavelength bands may be greater than 0.5, and the transmittances of light in the other N-k wavelength bands may be less than 0.5, where k is an integer that satisfies 2≤k<N. If incident light is white light, which includes all the visible light wavelength components equally, the filter array 110 modulates, on a region basis, the incident light into light having discrete peaks in intensity for wavelengths and superimposes and outputs light of these multiple wavelengths.

FIG. 4B is a diagram illustrating, as one example, a result obtained by averaging, on a wavelength band basis, the spectral transmittance of each of the wavelength bands W₁, W₂, . . . , W_{N} illustrated in FIG. 4A. The average transmittance is obtained by integrating the spectral transmittance T(λ) for each wavelength band and performing division using the bandwidth of the wavelength band. In this specification, the average transmittance value for each wavelength band obtained in this manner will be treated as the transmittance of the wavelength band. In this example, transmittance is prominently high in the three wavelength ranges corresponding to the local maxima P1, P3, and P5. In particular, transmittance is higher than 0.8 in the two wavelength ranges corresponding to the local maxima P3 and P5.

In the example illustrated in FIGS. 2A to 2D, a gray scale transmittance distribution is assumed in which the transmittance of each region may have any value greater than or equal to 0 and less than or equal to 1. However, a gray scale transmittance distribution is not always needed. For example, a binary scale transmittance distribution may be used in which the transmittance of each region may have either a value of around 0 or a value of around 1. In a binary scale transmittance distribution, each region transmits a large portion of light of at least two wavelength ranges among the wavelength ranges included in the target wavelength range, and does not transmit a large portion of light of the rest of the wavelength ranges. In this case, the “large portion” refers to about 80% or more.

Some cells among all the cells, for example, half the cells, may be replaced with transparent regions. Such transparent regions transmit light of each of the wavelength bands W₁, W₂, . . . , W_{N} included in the target wavelength range W at a similarly high transmittance, for example, 80% or higher. With such a configuration, the transparent regions are arranged, for example, in a checkerboard manner. That is, the regions having optical transmittance that varies with wavelength and the transparent regions may be arranged in an alternating manner in two directions of the arrayed regions in the filter array 110.

Data representing such a spatial distribution of the spectral transmittance of the filter array 110 is acquired beforehand on the basis of design data or by performing actual measurement calibration, and is stored in a storage medium of the image processing apparatus 200. This data is used in arithmetic processing to be described later.

The filter array 110 may be formed using, for example, multilayer films, organic materials, diffraction grating structures, metal-containing nanostructures, or metasurfaces. In a case where a multilayer film is used, for example, a dielectric multilayer film or a multilayer film including a metal layer may be used. In this case, the cells are formed such that at least one of the thickness, material, and stacking order of each multilayer film differs from cell to cell. As a result, spectral characteristics that are different from cell to cell can be realized. By using a multilayer film, a sharp rising edge and a sharp falling edge can be realized for spectral transmittance. A configuration using organic material can be realized by causing different cells to contain different pigments or dyes or by causing different cells to have different stacks of layers of materials. A configuration using a diffraction grating structure can be realized by causing different cells to have diffraction structures with different diffraction pitches or different depths. A metal-containing nanostructure can be fabricated using plasmon effect spectroscopy. Metasurfaces can be fabricated by nanofabricating dielectric materials in sizes smaller than the wavelength of incident light. In that structure, the refractive index for the incident light is spatially modulated. Alternatively, the incident light may be encoded by directly processing pixels included in the image sensor 160 without using the filter array 110.

From the foregoing, it can be said that the imaging device 100 has light receiving regions having different optical response characteristics from each other. In a case where the imaging device 100 has the filter array 110 including filters and the filters have irregularly different optical transmission characteristics from each other, the light receiving regions can be realized by the image sensor 160 with the filter array 110, which is disposed near or directly on the image sensor 160. In this case, the optical response characteristics of the light receiving regions are each determined on the basis of the transmittance spectra of the filters included in the filter array 110.

Alternatively, in a case where the imaging device 100 does not have the filter array 110, the light receiving regions can be realized, for example, by the image sensor 160 in which pixels are directly processed to have irregularly different optical response characteristics from each other. In this case, the optical response characteristics of the light receiving regions are each determined on the basis of the optical response characteristics of the pixels included in the image sensor 160.

The above-mentioned multilayer films, organic materials, diffraction grating structures, metal-containing nanostructures, or metasurfaces can encode incident light if they have configurations in which spectral transmittance is modulated to vary with position in a two-dimensional plane. Thus, the above-mentioned multilayer films, organic materials, diffraction grating structures, metal-containing nanostructures, or metasurfaces do not have to have configurations in which filters are arranged in an array.

Next, an example of signal processing performed by the image processing apparatus 200 will be described. The image processing apparatus 200 reconstructs a hyperspectral image 20, which is a multi-wavelength image, on the basis of the compressed image 10 output from the image sensor 160 and characteristics of a transmittance spatial distribution for each wavelength of the filter array 110. In this case, “multi-wavelength” refers to, for example, more wavelength ranges than 3-color wavelength ranges, which are RGB wavelength ranges, acquired by normal color cameras. The number of such wavelength ranges may be, for example, any number between 4 and about 100. The number of such wavelength ranges will be referred to as the “number of bands”. Depending on the application, the number of bands may exceed 100.

Data to be obtained is data of the hyperspectral image 20, and the data will be denoted by f. If the number of bands is N, f is data obtained by integrating data of N image bands f₁, f₂, . . . , f_{N}. In this case, suppose that the horizontal direction of the image is the x-direction, and the vertical direction of the image is the y-direction. When the number of pixels in the x-direction for the image data to be obtained is m, and the number of pixels in the y-direction for the image data to be obtained is n, each of the image data f₁, f₂, . . . , f_{N} has n×m pixel values. Thus, the data f is data having n×m×N elements. In contrast, data g of the compressed image 10 acquired through encoding and multiplexing performed by the filter array 110 has n×m elements. The data g can be expressed by Equation (1) below.

$$g = Hf = H [ \begin{matrix}{f}_{1} \\ {f}_{2} \\ ⋮ \\ {f}_{N}\end{matrix} ] \qquad ( 1 )$$

In Equation (1), f represents the data of the hyperspectral image expressed as a one-dimensional vector. Each of f₁, f₂, . . . , and f_{N} has n×m elements. Thus, the vector on the right side is strictly a one-dimensional vector having n×m×N rows and one column. The data g of the compressed image is calculated as a one-dimensional vector having n×m rows and one column. A matrix H represents a conversion in which individual components f₁, f₂, . . . , f_{N} of the vector f are encoded and intensity-modulated using encoding information that varies depending on the wavelength band, and are then added to one another. Thus, H denotes a matrix having n×m rows and n×m×N columns. Equation (1) can also be expressed as follows.

$$g = {( {pg}_{11} … {pg}_{1 m} … {pg}_{n 1} … {pg}_{nm} )}^{T} = {H ( {f}_{1} … {f}_{N} )}^{T} ,$$

where pgᵢⱼ denotes the pixel value in the i-th row and j-th column of the compressed image 10.

When the vector g and the matrix H are given, it seems that f can be calculated by solving an inverse problem of Equation (1). However, the number of elements n×m×N of the data f to be obtained is greater than the number of elements n×m of the acquired data g. This problem is thus an ill-posed problem, and the problem cannot be solved as is. Thus, the image processing apparatus 200 uses the sparsity of the images included in the data f and uses a compressed sensing method to obtain a solution. Specifically, the data f to be obtained is estimated by solving Equation (2) below.

$${f}^{′} = {arg min}_{f} \{ {‖ Hf - g ‖}_{2}^{2} + τ Φ ( f ) \} \qquad ( 2 )$$

In this case, f denotes estimated data of the data f. The first term in the braces of the equation above represents a shift between an estimation result Hf and the acquired data g, which is a so-called residual term. In this case, the sum of squares is treated as the residual term; however, an absolute value, a root-sum-square value, or the like may be treated as the residual term. The second term in the braces is a regularization term or a stabilization term. Equation (2) means to obtain f that minimizes the sum of the first term and the second term. The function in the braces in Equation (2) is called an evaluation function. The image processing apparatus 200 can cause the solution to converge through a recursive iterative operation and can calculate f that minimizes the evaluation function as a final solution f.

The first term in the braces of Equation (2) refers to an arithmetic operation for obtaining the sum of squares of the differences between the acquired data g and Hf, which is obtained by converting f in the estimation process using the matrix H. The second term Φ(f) is a constraint for regularization of f and is a function that reflects sparse information regarding estimated data. This function has the effect of making the estimated data smooth and stable. The regularization term can be expressed using, for example, discrete cosine transformation (DCT), wavelet transform, Fourier transform, or total variation (TV) of f. For example, in a case where total variation is used, stabilized estimated data can be acquired in which the effect of noise of the data g, observation data, is suppressed. The sparsity of the target 70 in the space of each regularization term differs with the texture of the target 70. A regularization term for which the texture of the target 70 becomes sparser in the space of the regularization term may be selected. Alternatively, regularization terms may be included in the arithmetic operation. τ is a weighting factor. The greater the weighting factor τ, the sparser the solution is calculated. The smaller the weighting factor τ, the lower the convergence to the solution. The weighting factor τ is set to an appropriate value with which f is converged to some degree and is not too sparse.

Through the above-mentioned process, the hyperspectral image 20 can be reconstructed on the basis of the compressed image 10 acquired by the image sensor 160. Details of the method for reconstructing the hyperspectral image 20 are disclosed in U.S. Pat. No. 9,599,511.

### 2. Configuration Example of Imaging System that Reduces Reconstruction Errors of Reconstructed Images

In a case where the target 70 contains a fine structure, the size of the fine structure in the compressed image 10 in which the target 70 appears is not sufficiently large relative to the pixel pitch, and the luminance change in a reconstructed image is not small. This may increase the reconstruction error of the reconstructed image. The following will describe a method for reducing the reconstruction error of a reconstructed image even in a case where the target 70 contains a fine structure.

### 2.1. Reducing Reconstruction Error of Reconstructed Image Using Low-Pass Filter

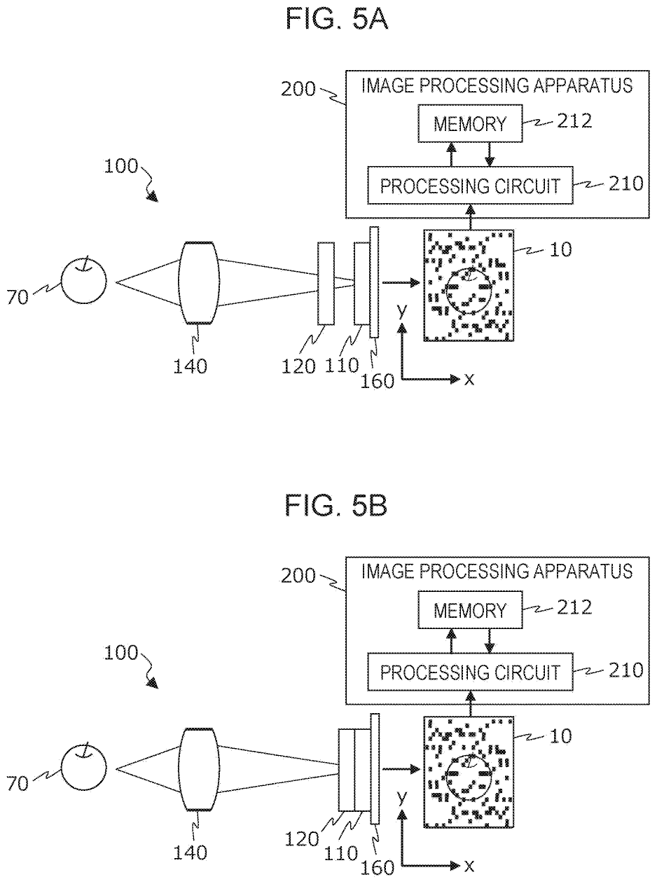

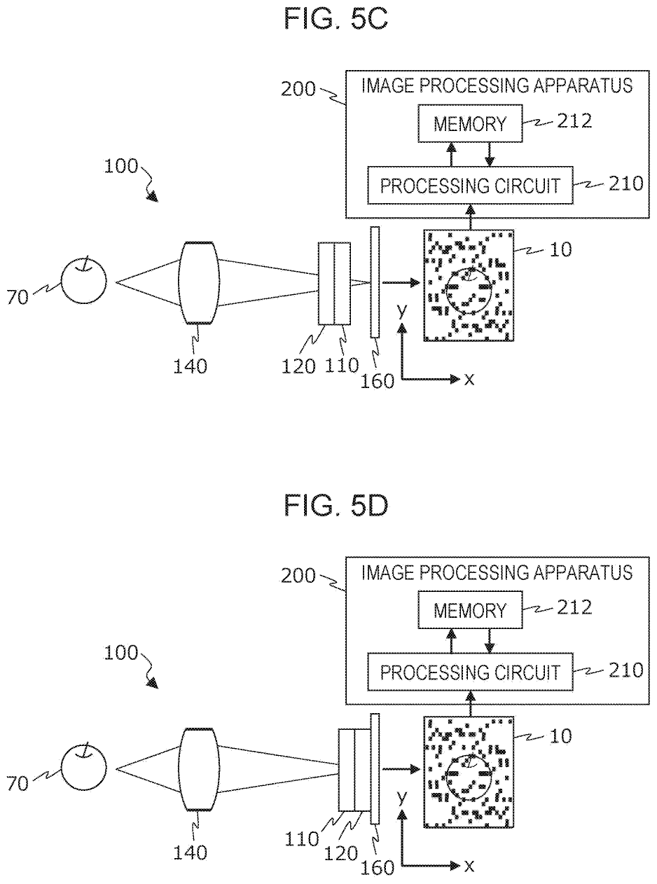

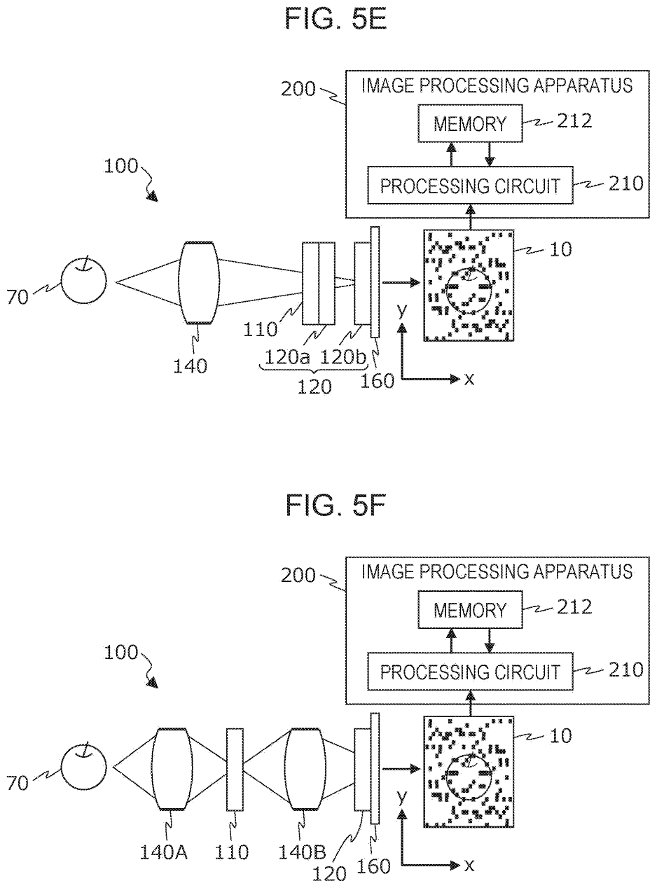

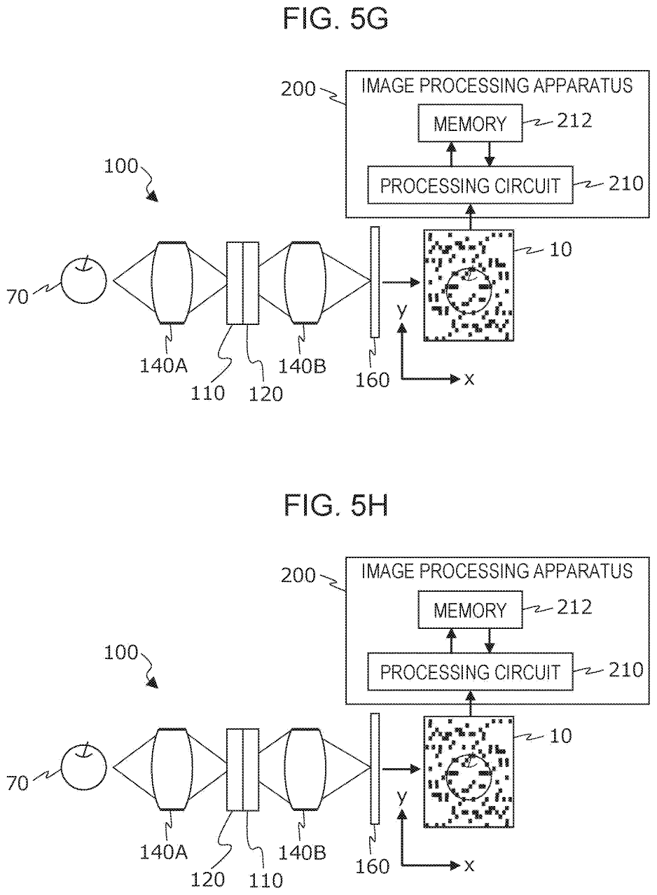

First, with reference to FIGS. 5A to 5H, configuration examples of imaging systems according to the present embodiment that can reduce the reconstruction error of a reconstructed image even in a case where the target 70 contains a fine structure will be described. FIGS. 5A to 5H are diagrams schematically illustrating configuration examples of imaging systems according to the present embodiment that reduce the reconstruction error of a reconstructed image. The imaging systems illustrated in FIGS. 5A to 5H include the imaging device 100 and the image processing apparatus 200.

The image processing apparatus 200 includes a processing circuit 210 and a memory 212. The processing circuit 210 generates a hyperspectral image 20 on the basis of a compressed image 10 acquired by the imaging device 100. In the compressed image 10, information regarding four or more wavelength bands is compressed. The hyperspectral image 20 includes four or more reconstructed images corresponding to the four or more respective wavelength bands. A computer program executed by the processing circuit 210 is stored in the memory 212, such as a read-only memory (ROM) or a random access memory (RAM). The processing circuit 210 and the memory 212 may be integrated on one circuit board or on separate circuit boards. The processing circuit 210 may also be distributed across multiple circuits. The processing circuit 210, the memory 212, or both may be installed at a remote location or remote locations separate from the other constituent elements via a wired or wireless communication network.

The imaging device 100 includes a low-pass filter 120 in addition to the constituent elements illustrated in FIGS. 1A to 1D. The image sensor 160 detects light through the low-pass filter 120 and the filter array 110.

The filter array 110 may include, for example, filter groups arranged in two dimensions. Each filter group includes types of filters having different transmittance spectra from each other and arranged in two dimensions. In each filter group, the types of filters are arranged adjacent to each other. Each filter group may include types of filters arranged in, for example, four rows and four columns, six rows and six columns, or eight rows and eight columns. The number of types may be, for example, greater than or equal to 16, greater than or equal to 36, or greater than or equal to 64.

In all of the filter groups, the arrangement of the types of filters may be the same, for example. Alternatively, the arrangement of the types of filters may be the same in some of the filter groups, and the arrangement of the types of filters may be different in the remaining filter groups. In all of the filter groups, the arrangement of the types of filters may be different.

The role of the low-pass filter 120 is as follows. The low-pass filter 120 reduces spatial frequency components of the light incident on itself that are greater than or equal to a specific frequency. The transmittance of the low-pass filter 120 for spatial frequencies greater than or equal to the specific frequency is lower than that of the low-pass filter 120 for spatial frequencies less than the specific frequency. The transmittance of the low-pass filter 120 for the spatial frequencies greater than or equal to the specific frequency may be, for example, 10% or less, 5% or less, or 1% or less. The transmittance of the low-pass filter 120 for the spatial frequencies less than the specific frequency may be, for example, 60% or less, 80% or less, or 90% or less. The specific frequency of the low-pass filter 120 will be described below.

The low-pass filter 120 may have a predetermined refractive index, for example. Alternatively, the low-pass filter 120 may be an optical unit obtained by combining optical members, such as a birefringent plate, a wave plate, an optical system, and a transparent plate, for example. The low-pass filter 120 may be, for example, a phase-modulating diffraction grating, namely a phase grating. In this specification, the low-pass filter 120 is also referred to as an “optical element”.

Regarding light from the target 70 that is incident on the image sensor 160, the low-pass filter 120 can reduce the spatial frequency components of the light that are greater than or equal to the specific frequency. Thus, even in a case where the target 70 contains a fine structure, the change in the luminance of a reconstructed image generated on the basis of the compressed image 10 will be small, and the reconstruction error of the reconstructed image can be reduced.

An example of the arrangement of the constituent elements including the low-pass filter 120 is as follows.

In the example illustrated in FIG. 5A, the optical system 140, the low-pass filter 120, the filter array 110, and the image sensor 160 are arranged in this order. The filter array 110 is disposed on the image sensor 160. The filter array 110 may be integrated on the image sensor 160. Alternatively, the filter array 110 may be bonded onto the image sensor 160 with a spacer, an adhesive, or both interposed therebetween. The filter array 110 may be larger or smaller than the image sensor 160 in size. Alternatively, the filter array 110 may match the image sensor 160 in size. The low-pass filter 120 is disposed so as to be spaced apart from the filter array 110.

In the example illustrated in FIG. 5B, the low-pass filter 120 is disposed on the filter array 110, unlike the example illustrated in FIG. 5A. The low-pass filter 120 may be integrated on the filter array 110. Alternatively, the low-pass filter 120 may be bonded onto the filter array 110.

In the example illustrated in FIG. 5C, the filter array 110 is disposed so as to be spaced apart from the image sensor 160, unlike the example illustrated in FIG. 5A. The low-pass filter 120 is disposed on the filter array 110.

In the example illustrated in FIG. 5D, the filter array 110 and the low-pass filter 120 are switched, unlike the example illustrated in FIG. 5B. The low-pass filter 120 may be integrated on the image sensor 160. Alternatively, the low-pass filter 120 may be bonded onto the image sensor 160 with a spacer, an adhesive, or both interposed therebetween. The filter array 110 may be integrated on the low-pass filter 120. Alternatively, the filter array 110 may be bonded onto the low-pass filter 120 with a spacer, an adhesive, or both interposed therebetween.

In the example illustrated in FIG. 5E, the optical system 140, the filter array 110, the low-pass filter 120, and the image sensor 160 are arranged in this order. Note that the low-pass filter 120 is divided into a first portion 120a and a second portion 120b. In a case where the low-pass filter 120 is an optical unit obtained by combining optical members, the first portion 120a is part of the optical members, and the second portion 120b is the rest of the optical members.

The second portion 120b is disposed on the image sensor 160. The first portion 120a is disposed so as to be spaced apart from the second portion 120b. The filter array 110 is disposed on the first portion 120a. The combination of the first portion 120a and the second portion 120b plays the same role as the low-pass filter 120 illustrated in FIG. 5A.

In the example illustrated in FIG. 5F, the optical system 140A, the filter array 110, the optical system 140B, the low-pass filter 120, and the image sensor 160 are arranged in this order. The low-pass filter 120 is disposed on the image sensor 160. The filter array 110 is disposed so as to be spaced apart from the low-pass filter 120 with the optical system 140B interposed therebetween.

In the example illustrated in FIG. 5G, the low-pass filter 120 is disposed so as to be spaced apart from the image sensor 160 with the optical system 140B interposed therebetween, unlike the example illustrated in FIG. 5F. The filter array 110 is disposed on the low-pass filter 120.

In the example illustrated in FIG. 5H, the filter array 110 and the low-pass filter 120 are switched, unlike the example illustrated in FIG. 5G.

In the examples illustrated in FIGS. 5A to 5C and FIG. 5H, the filter array 110 is located between the low-pass filter 120 and the image sensor 160. In the examples illustrated in FIGS. 5D to 5G, the low-pass filter 120 is located between the filter array 110 and the image sensor 160. As long as the filter array 110 and the low-pass filter 120 are located along the optical path of the light from the target 70 that is incident on the image sensor 160, the constituent elements may be disposed in a manner different from the examples illustrated in FIGS. 5A to 5H.

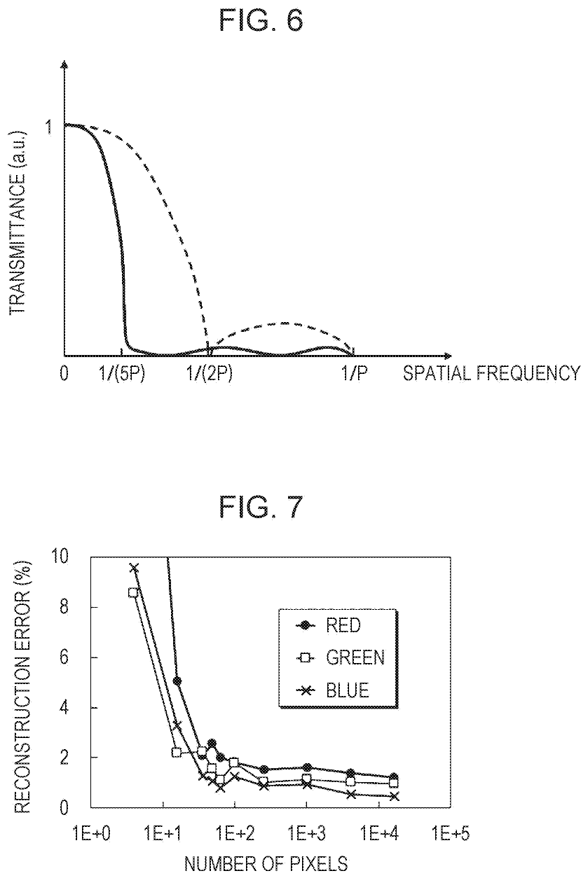

Next, the specific frequency of the low-pass filter 120 will be described with reference to FIG. 6. FIG. 6 is a graph illustrating the transmission spectra of low-pass filters used in the imaging device 100 according to the present embodiment and existing cameras. The vertical axis and the horizontal axis illustrated in FIG. 6 represent transmittance and spatial frequency, respectively. The solid line and dashed line illustrated in FIG. 6 represent the transmission spectrum of the low-pass filter used in the imaging device 100 according to the present embodiment and that of low-pass filters used in the existing cameras, respectively. In FIG. 6, “P” represents the pixel pitch of the image sensor 160.

The existing cameras may include low-pass filters to remove moiré. Moiré is a stripe pattern that can appear in an image. In a case where a target contains a periodic structure, moiré appears when the size of the period of the periodic structure is about the pixel pitch in an image in which the target appears.

In the example illustrated in FIG. 6, the low-pass filters used in the existing cameras effectively reduce spatial frequency components greater than or equal to 1/(2P), which is the Nyquist frequency, to remove moiré, as represented by the dashed line. The specific frequency in this case is 1/(2P).

In contrast, the low-pass filter 120 used in the imaging device according to the present embodiment reduces spatial frequency components greater than or equal to 1/(5P), as represented by the solid line. In the imaging device 100 according to the present embodiment, the reconstruction error of a reconstructed image can be reduced by the low-pass filter 120 effectively reducing the spatial frequency components greater than or equal to 1/(5P). The specific frequency in this case is 1/(5P).

Note that the specific frequency in the example illustrated in FIG. 6 is a spatial frequency where the absolute value of the slope of transmittance with respect to spatial frequency in the transmittance spectrum reaches a maximum. The specific frequency is the lowest spatial frequency at which the transmittance becomes less than or equal to a constant value (for example, 0.5, 0.2, 0.1, 0.05, or the like).

Next, with reference to FIG. 7, a method for determining the specific frequency of the low-pass filter 120 used in the imaging device 100 according to the present embodiment will be described. FIG. 7 is a graph illustrating, about the target 70 including color charts, the reconstruction error of a reconstructed image when red, green, and blue regions are extracted from the compressed image 10 while varying the number of pixels in each of the red, green, and blue regions. The horizontal axis illustrated in FIG. 7 represents the number of pixels in a portion corresponding to each color chart extracted from the compressed image 10, and the vertical axis illustrated in FIG. 7 represents reconstruction error, which is

$$100 \times ( √ ( MSE ) ) / 255.$$

Mean squared error (MSE) is the mean squared error about a pixel value vᵣ₍ᵢⱼ₎ of a pixel pᵣ₍ᵢⱼ₎ included in the reconstructed image and a pixel value v_{gt(ij)} of a pixel p_{gt(ij)} of its correct image. 255 is the maximum value of the signal. 1E+n means 10ⁿ.

As the number of pixels of the portion corresponding to each color chart extracted from the compressed image 10, the number of pixels arranged in two dimensions was used. As the number of pixels, 2×2, 4×4, 6×6, 7×7, 8×8, and the like were used.

As illustrated in FIG. 7, in a case where the number of pixels is 2×2, the reconstruction error of the reconstructed image for the color charts of the above-mentioned three colors exceeds 8%. In a case where the number of pixels is 4×4, the reconstruction error of the reconstructed image for the green and blue color charts is less than or equal to 4%; however, the reconstruction error of the reconstructed image for the red color chart exceeds 4%. In contrast, in a case where the number of pixels is greater than or equal to 6×6, the reconstruction error of the reconstructed image for the color charts of the above-mentioned three colors is less than or equal to 3%. Based on this, in a case where the number of pixels is greater than or equal to 5×5, the reconstruction error of the reconstructed image for the color charts of the above-mentioned three colors can be less than or equal to 4%.

Thus, the reconstruction error of the reconstructed image can be less than or equal to 4% if the spatial frequency components of the light from the target 70 that are greater than or equal to 1/(5P) can be effectively reduced. As a result, the specific frequency of the low-pass filter 120 used in the imaging device 100 according to the present embodiment can be, for example, less than or equal to 1/(5P). The specific frequency is lower than the Nyquist frequency mentioned above.

When the specific frequency is set too low, certain spatial frequency components of the light from the target 70 that is incident on the image sensor 160 may be removed even though the spatial frequency components are needed to generate the hyperspectral image 20. Based on this, the specific frequency can be set, for example, to a value greater than or equal to 1/(10P) and less than or equal to 1/(5P). Alternatively, the specific frequency may be greater than or equal to 1/(9P) and less than or equal to 1/(5P), may be greater than or equal to 1/(8P) and less than or equal to 1/(5P), may be greater than or equal to 1/(7P) and less than or equal to 1/(5P), or may be greater than or equal to 1/(6P) and less than or equal to 1/(5P), for example.

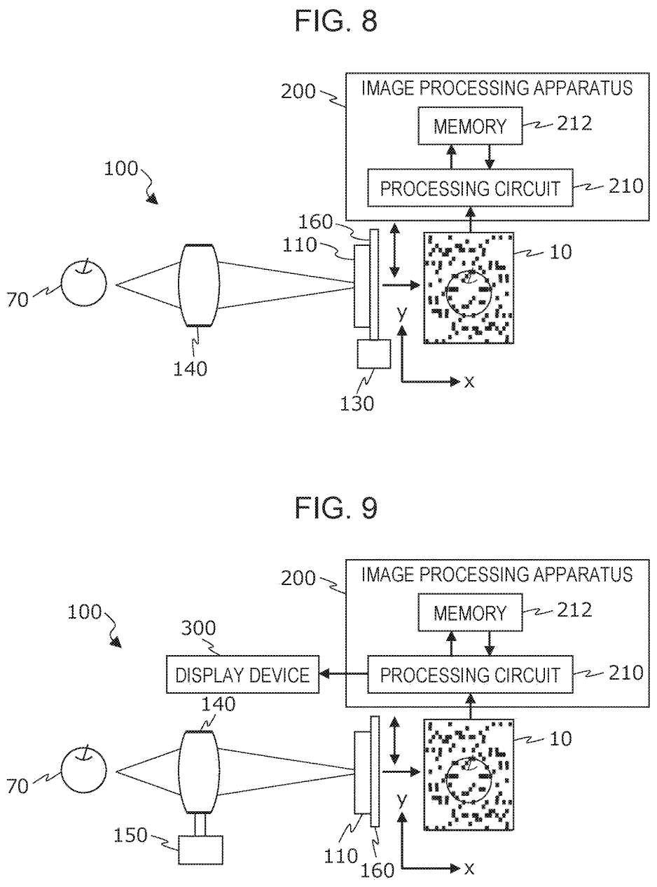

Regarding the light from the target 70 that is incident on the image sensor 160, as a method for reducing spatial frequency components of the light that are greater than or equal to the specific frequency, the image sensor 160 may be vibrated instead of using the low-pass filter 120. FIG. 8 is a diagram schematically illustrating another configuration example of the imaging system according to the present embodiment that reduces the reconstruction error of a reconstructed image. In the imaging system illustrated in FIG. 8, the imaging device 100 includes, in addition to the constituent elements illustrated in FIG. 1A, a vibration device 130 that causes the image sensor 160 to vibrate in a direction that intersects the direction of light incidence from the target 70. The vibration device 130 can be, for example, an actuator. The double arrow illustrated in FIG. 8 indicates the vibration direction of the image sensor 160.

Similar to the low-pass filter 120, regarding the light from the target 70 that is incident on the image sensor 160, the spatial frequency components of the light that are greater than or equal to the specific frequency can be reduced by the vibration device 130 causing the image sensor 160 to vibrate. The specific frequency is as described above with reference to FIG. 7.

From the above, in the imaging device 100 according to the present embodiment, regarding the light from the target 70 that is incident on the image sensor 160, the spatial frequency components of the light that are greater than or equal to the specific frequency can be reduced by using the low-pass filter 120 or by vibrating the image sensor 160. As a result, the change in the luminance of the reconstructed images generated on the basis of the compressed image 10 is smaller, so that the reconstruction errors of the reconstructed images can be reduced.

### 2.2. Reducing Reconstruction Error of Reconstructed Image by Being out of Focus

Next, with reference to FIG. 9, yet another configuration example of the imaging system according to the present embodiment will be described that reduces the reconstruction error of a reconstructed image even in a case where the target 70 contains a fine structure. FIG. 9 is a diagram schematically illustrating yet another configuration example of the imaging device according to the present embodiment that reduces the reconstruction error of a reconstructed image. In the imaging system illustrated in FIG. 9, the imaging device 100 includes an adjustment device 150 that adjusts the focus position of the optical system 140, and a display device 300, in addition to the constituent elements illustrated in FIG. 1A. The processing circuit 210 controls the operation of the adjustment device 150. The display device 300 is not a constituent element of the imaging system and may be an external constituent element.

The adjustment device 150 adjusts the focus position of the optical system 140 so that the focus position of the optical system 140 is shifted from its in-focus position. As a result, the resolution of the compressed image 10 is reduced, and regarding the light from the target 70 that is incident on the image sensor 160, the spatial frequency components of the light that are greater than or equal to the specific frequency can be reduced. The specific frequency is as described above with reference to FIG. 7. As a result, the change in the luminance of the reconstructed image generated on the basis of the compressed image 10 is smaller, so that the reconstruction error of the reconstructed image can be reduced.

### 2.2.1. Processing Operation Example 1

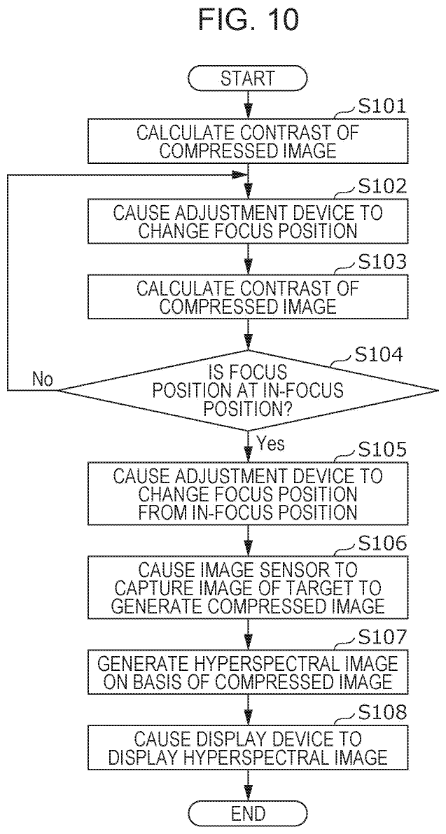

Next, with reference to FIG. 10, Example 1 of a processing operation will be described that is performed by the processing circuit 210 in the imaging system according to the present embodiment. FIG. 10 is a flowchart schematically illustrating Example 1 of the processing operation performed by the processing circuit 210. The processing circuit 210 performs the operations in Steps S101 to S108 illustrated in FIG. 10.

### Step S101

The processing circuit 210 causes the image sensor 160 to capture an image of the target 70 to generate a compressed image 10 and calculates the contrast of the compressed image 10 acquired from the image sensor 160.

### Step S102

The processing circuit 210 causes the adjustment device 150 to change the focus position of the optical system 140.

### Step S103

The processing circuit 210 causes the image sensor 160 to capture an image of the target 70 to generate a compressed image 10 and calculates the contrast of the compressed image 10 acquired from the image sensor 160.

### Step S104

The processing circuit 210 determines whether or not the focus position of the optical system 140 is at its in-focus position. In a case where the contrast of the compressed image 10 is at its maximum, the focus position of the optical system 140 is at its in-focus position. Thus, this determination is made by examining the contrast of the compressed image 10.

In a case where a determination of Yes is obtained, the processing circuit 210 performs the operation in Step S105. In a case where a determination of No is obtained, the processing circuit 210 performs the operation in Step S102 again.

In this manner, the processing circuit 210 causes the image sensor 160 to generate compressed images 10 under respective conditions in which the focus position of the optical system 140 differs. The processing circuit 210 further determines, on the basis of the compressed images 10, a first condition under which the focus position of the optical system 140 is at its in-focus position.

The operations in Steps S101 to S104 are the same as those in the so-called contrast-detection autofocus in a normal camera. Instead of the operations in Steps S101 to S104, the operations in the so-called phase-detection autofocus in a normal camera may be performed. That is, a portion of light from the target 70 that is incident on the image sensor 160 is taken out by, for example, a beam splitter, and the portion is divided into two parts to acquire two images. In a case where the two images overlap without any shift, the focus position of the optical system 140 is at its in-focus position. Thus, the above-mentioned determination may be made by checking whether or not the two images overlap without any shift.

### Step S105

The processing circuit 210 determines a second condition different from the first condition, and causes the adjustment device 150 to change the focus position of the optical system 140 from its in-focus position. The second condition is that regarding the light from the target 70 that is incident on the image sensor 160, the resolution of the compressed image 10 be reduced to reduce the spatial frequency components of the light that are greater than or equal to the specific frequency. The optical system 140 includes one or more lenses, and the one or more lenses include a first lens. Among the one or more lenses, the first lens is the closest to the image sensor 160. Since the focus position of the optical system 140 is shifted from its in-focus position, the distance between the first lens and the light receiving surface of the image sensor 160 is different from the back focus of the optical system 140 under the second condition. The back focus of the optical system 140 is the distance from the first lens to the focal plane of the optical system 140.

### Step S106

The processing circuit 210 causes the image sensor 160 to capture an image of the target 70 under the second condition to generate a compressed image 10.

### Step S107

The processing circuit 210 generates a hyperspectral image 20 on the basis of the compressed image 10.

### Step S108

The processing circuit 210 causes the display device 300 to display the hyperspectral image 20. The processing circuit 210 may further cause the display device 300 to display the compressed image 10 generated under the first or second condition.

The above-mentioned operations make it possible to reduce the reconstruction error of a reconstructed image even in a case where the target 70 contains a fine structure.

### 2.2.2. Processing Operation Example 2

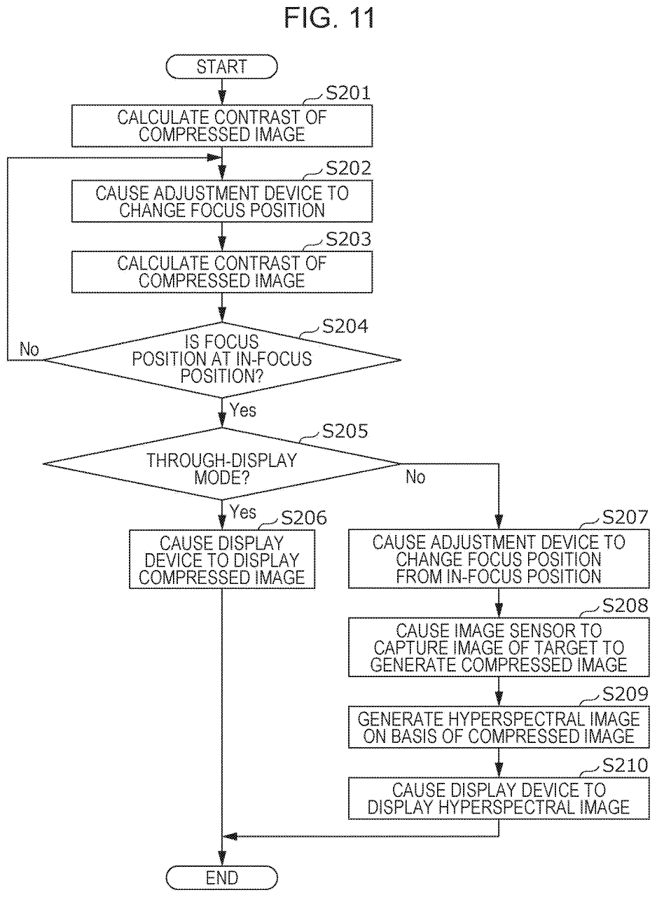

Next, with reference to FIG. 11, Example 2 of the processing operation will be described that is performed by the processing circuit 210 in the imaging system according to the present embodiment. FIG. 11 is a flowchart schematically illustrating Example 2 of the processing operation performed by the processing circuit 210. The processing circuit 210 performs the operations in Steps S201 to S210 illustrated in FIG. 11.

### Steps S201 to S204

The operations in Steps S201 to S204 are the same as those in Steps S101 to S104 illustrated in FIG. 10.

### Step S205

Among a through-display mode and a spectral display mode, the processing circuit 210 determines whether to operate in the through-display mode. In the through-display mode, the compressed image 10 is displayed without displaying the hyperspectral image 20. In the spectral display mode, the hyperspectral image 20 is displayed. This determination may be made on the basis of an input via a user interface (UI) from the user. For example, from the type, state, or both of the target 70, the user may determine that the hyperspectral image 20 does not have to be displayed.

In a case where a determination of Yes is obtained, the processing circuit 210 performs the operation in Step S206 as the through-display mode. In a case where a determination of No is obtained, the processing circuit 210 performs the operations in Steps S207 to S210 as the spectral display mode. In this manner, the processing circuit 210 determines whether to operate in the through-display mode or the spectral display mode.

In this specification, the through-display mode is also referred to as a “first mode”, and the spectral display mode as a “second mode”.

### Step S206

The processing circuit 210 causes the display device 300 to display the compressed image 10 generated under the first condition. The compressed image 10 generated under the first condition is an image that does not give a sense of unnaturalness to the user.

### Steps S207 to S210

The operations in Steps S207 to S210 are the same as those in Steps S105 to S108 illustrated in FIG. 10.

In a case where the through-display mode is selected through the operations described above, the compressed image 10 that does not give a sense of unnaturalness to the user can be displayed.

### 2.2.3. Processing Operation Example 3

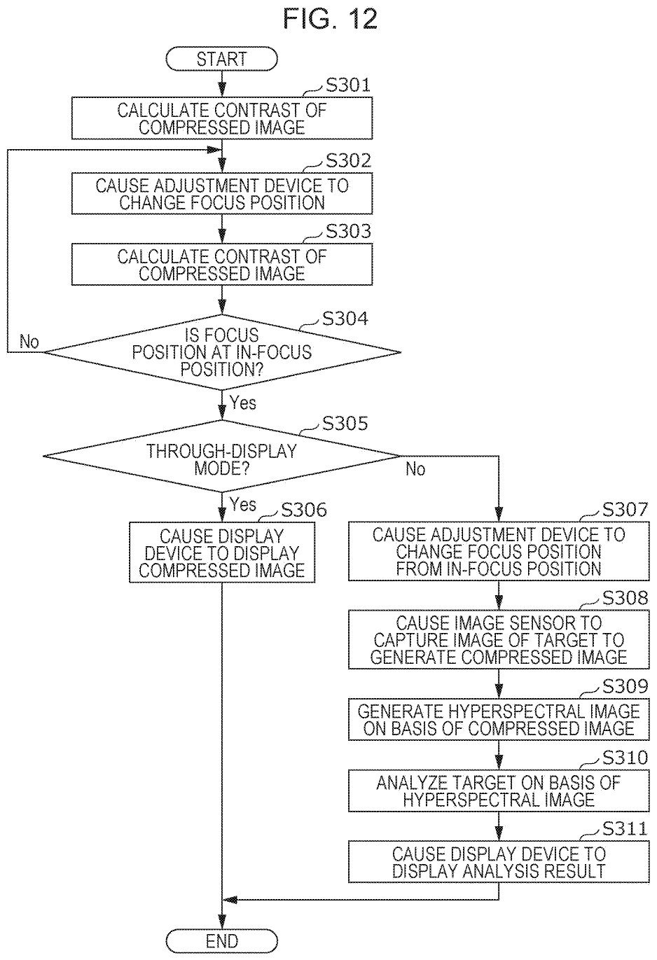

Next, with reference to FIG. 12, Example 3 of the processing operation will be described that is performed by the processing circuit 210 in the imaging system according to the present embodiment. FIG. 12 is a flowchart schematically illustrating Example 3 of the processing operation performed by the processing circuit 210. The processing circuit 210 performs the operations in Steps S301 to S311 illustrated in FIG. 12.

### Steps S301 to S309

The operations in Steps S301 to S309 are the same as those in Steps S201 to S209 illustrated in FIG. 11.

### Step S310

The processing circuit 210 analyzes the target 70 on the basis of the hyperspectral image 20. Examples of analysis include food inspection, biopsies, drug development, and mineral composition analysis.

### Step S311

The processing circuit 210 causes the display device 300 to display the analysis result. The processing circuit 210 may further cause the display device 300 to display the hyperspectral image 20, the compressed image 10 generated under the first or second condition, or the hyperspectral image 20 and compressed image 10.

In a case where the spectral display mode is selected through the operations described above, the result of the analysis of the target 70 can be obtained.

### 2.2.4. Processing Operation Example 4

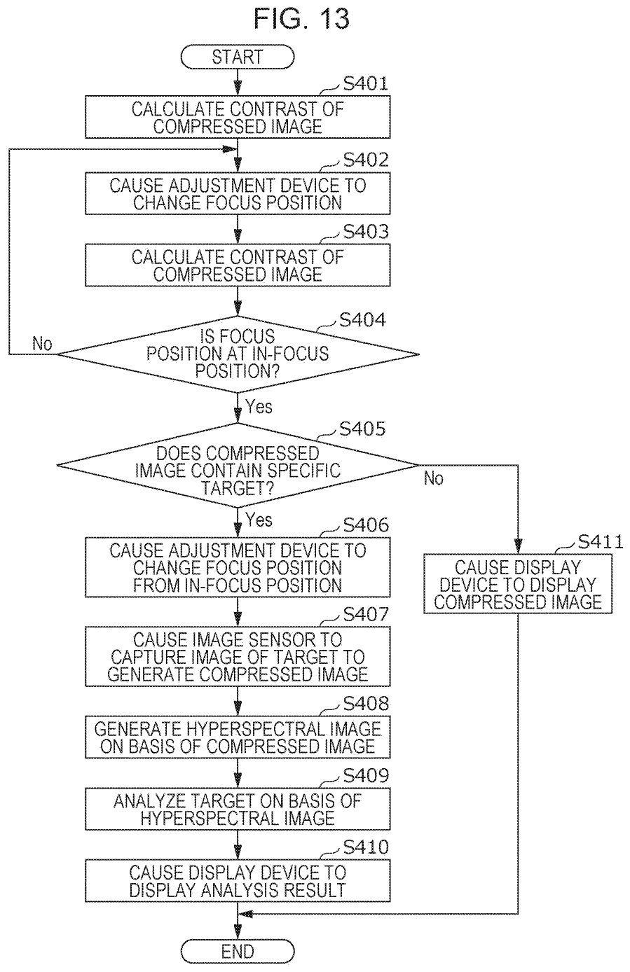

Next, with reference to FIG. 13, Example 4 of the processing operation will be described that is performed by the processing circuit 210 in the imaging system according to the present embodiment. FIG. 13 is a flowchart schematically illustrating Example 4 of the processing operation performed by the processing circuit 210. The processing circuit 210 performs the operations in Steps S401 to S411 illustrated in FIG. 13.

### Steps S401 to S404

The operations in Steps S401 to S404 are the same as those in Steps S301 to S304 illustrated in FIG. 12.

### Step S405

The processing circuit 210 determines whether or not the compressed image 10 contains a specific target 70. This determination can be made, for example, by using a model that takes the compressed image 10 as input and the recognition result of the target 70 that appears in the compressed image 10 as output.

The model is generated through training using a machine learning algorithm on various targets 70. In machine learning, algorithms such as deep learning, support vector machines, decision trees, genetic programming, or Bayesian networks, for example, can be used. In a case where deep learning is used, algorithms such as convolutional neural networks (CNN) or recurrent neural networks (RNN), for example, can be used.

Alternatively, the above-mentioned determination may be made by applying known image recognition techniques to the target 70 extracted from the compressed image 10 using edge detection.

In a case where a determination of Yes is obtained, the processing circuit 210 performs the operations in Steps S406 to S410 as the spectral display mode. In a case where a determination of No is obtained, the processing circuit 210 performs the operation in Step S411 as the through-display mode. In this manner, the processing circuit 210 determines whether to operate in the spectral display mode or the through-display mode on the basis of the determination result.

### Steps S406 to S410

The operations in Steps S406 to S410 are the same as those in Steps S307 to S311 illustrated in FIG. 12.

### Step S411

The processing circuit 210 causes the display device 300 to display the compressed image 10 generated under the first condition.

Since the hyperspectral image 20 is generated in a case where the compressed image 10 contains a specific target 70 and the hyperspectral image 20 is not generated in a case where the compressed image 10 does not contain a specific target 70, the above-mentioned operations make it possible to reduce the amount of processing in the processing circuit 210. The above-mentioned operations can be applied, for example, to the inspection of the target 70 carried by a conveyor belt in a factory.

### 2.3. UI Displayed on Display Device 300

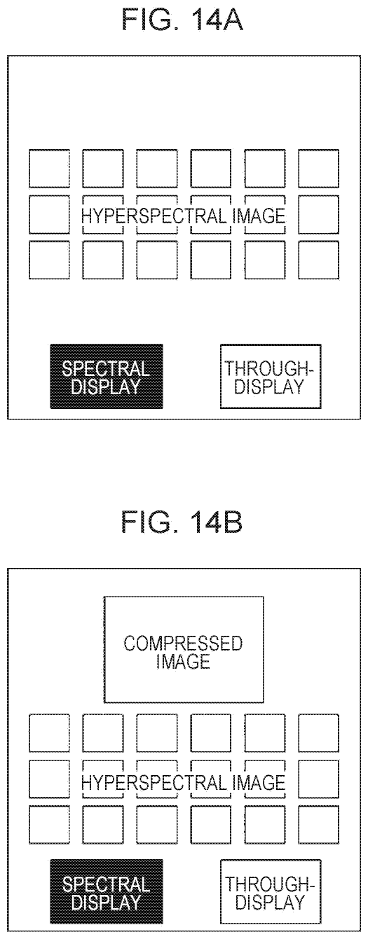

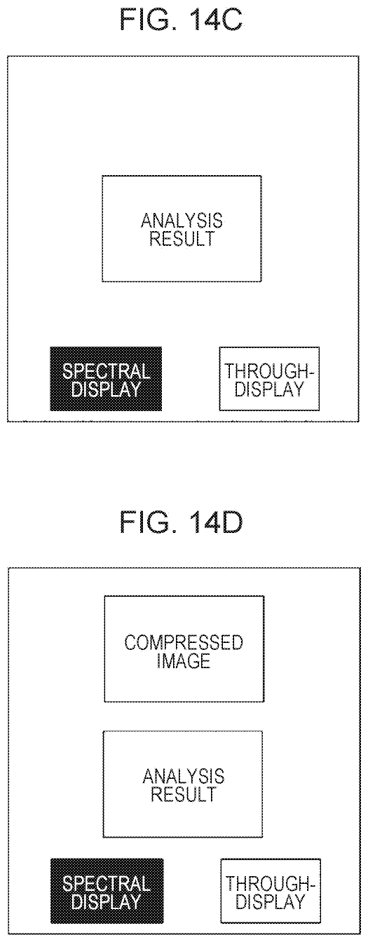

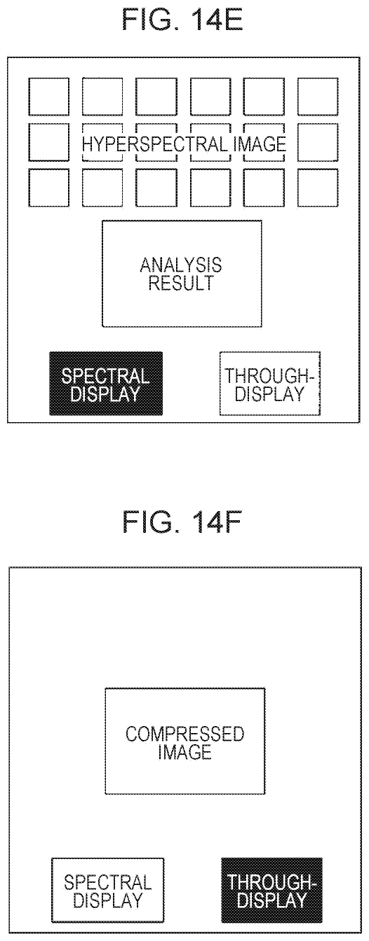

Next, UI examples displayed on the display device 300 will be described with reference to FIGS. 14A to 14F. FIGS. 14A to 14E are diagrams schematically illustrating UI examples displayed on the display device 300 in the spectral display mode. FIG. 14F is a diagram schematically illustrating a UI example displayed on the display device 300 in the through-display mode.

The example illustrated in FIG. 14A corresponds to the UI displayed on the display device 300 in Step S210 illustrated in FIG. 11. In the example illustrated in FIG. 14A, the hyperspectral image 20 is displayed in the center portion of the UI. A “spectral display” button and a “through-display” button are displayed in the bottom portion of the UI, and the “spectral display” button is pressed by the user. When the user presses the “spectral display” button or the “through-display” button, the processing circuit 210 determines whether to operate in the spectral display mode or the through-display mode on the basis of the input via the UI from the user. In the example illustrated in FIG. 14A, the hyperspectral image 20, which is more accurate, can be displayed.

The example illustrated in FIG. 14B corresponds to the UI displayed on the display device 300 in Step S210 illustrated in FIG. 11. In the example illustrated in FIG. 14B, the compressed image 10 generated under the first or second condition is displayed in the top portion of the UI. The hyperspectral image 20 is displayed in the center portion of the UI. The “spectral display” button and the “through-display” button are displayed in the bottom portion of the UI. In the example illustrated in FIG. 14B, while displaying the hyperspectral image 20, which is more accurate, the compressed image 10 that does not give a sense of unnaturalness to the user can be displayed in a case where the compressed image 10 is generated under the first condition.

The example illustrated in FIG. 14C corresponds to the UI displayed on the display device 300 in Step S311 illustrated in FIG. 12 and Step S410 illustrated in FIG. 13. In the example illustrated in FIG. 14C, the results of the analysis are displayed in the center portion of the UI. The “spectral display” button and the “through-display” button are displayed in the bottom portion of the UI. In the example illustrated in FIG. 14C, more accurate analysis results can be displayed.

The example illustrated in FIG. 14D corresponds to the UI displayed on the display device 300 in Step S311 illustrated in FIG. 12 and Step S410 illustrated in FIG. 13. In the example illustrated in FIG. 14D, the compressed image 10 generated under the first or second condition is displayed in the top portion of the UI. The results of the analysis are displayed in the center portion of the UI. The “spectral display” button and the “through-display” button are displayed in the bottom portion of the UI. In the example illustrated in FIG. 14D, while displaying more accurate analysis results, the compressed image 10 that does not give a sense of unnaturalness to the user can be displayed in a case where the compressed image 10 is generated under the first condition.

The example illustrated in FIG. 14E corresponds to the UI displayed on the display device 300 in Step S311 illustrated in FIG. 12 and Step S410 illustrated in FIG. 13. Unlike the example illustrated in FIG. 14D, not the compressed image 10 but the hyperspectral image 20 is displayed in the top portion of the UI in the example illustrated in FIG. 14E. In the example illustrated in FIG. 14E, while displaying more accurate analysis results, the hyperspectral image 20, which is more accurate, can be displayed.

The example illustrated in FIG. 14F corresponds to the UI displayed on the display device 300 in Step S206 illustrated in FIG. 11, Step S306 illustrated in FIG. 12, and Step S411 illustrated in FIG. 13. In the example illustrated in FIG. 14F, the compressed image 10 generated under the first condition is displayed in the center portion of the UI. The “spectral display” button and the “through-display” button are displayed in the bottom portion of the UI, and the “through-display” button is pressed by the user. In the example illustrated in FIG. 14F, the compressed image 10 that does not give a sense of unnaturalness to the user can be displayed.

From the above-mentioned description, in an imaging system according to the present embodiment, high spatial frequency components of light from a target that is incident on the image sensor 160 can be reduced by adjusting the focus position of the optical system 140 so that the focus position of the optical system 140 is shifted from its in-focus position. As a result, the changes in luminance of the reconstructed images generated on the basis of the compressed image 10 are smaller, so that the reconstruction errors of the reconstructed images can be reduced.

### 3. Appendix

The description of the above-mentioned embodiments discloses the following techniques.

### Technique 1

An imaging device including:
an optical filter including regions having different transmittance spectra from each other,
an optical element, and
an image sensor that detects light through the optical element and the optical filter to generate a compressed image in which information regarding four or more wavelength bands is compressed, and
the optical element reduces a spatial frequency component of light incident on the optical element that is greater than or equal to a specific frequency, and
the specific frequency is less than or equal to 1/(5P) when a pixel pitch of the image sensor is P.

This imaging device can reduce the reconstruction error of a reconstructed image when generating the reconstructed image on the basis of the compressed image.

### Technique 2

The imaging device according to Technique 1,
in which the specific frequency is greater than or equal to 1/(10P).

Regarding light from a target that is incident on the image sensor, this imaging device can suppress the removal of the spatial frequency component of the light that is needed to generate the reconstructed image.

### Technique 3

The imaging device according to Technique 1 or 2,
in which the optical element is positioned between the optical filter and the image sensor.

In this imaging device, the distance between the optical filter and the optical element is smaller than the distance between the optical filter and the image sensor.

### Technique 4

The imaging device according to Technique 1 or 2,
in which the optical filter is positioned between the optical element and the image sensor.

In this imaging device, the distance between the optical element and the optical filter is smaller than the distance between the optical element and the image sensor.

### Technique 5

An imaging system including:
the imaging device according to any one of Techniques 1 to 4, and
a processing circuit that generates, based on the compressed image, four or more images corresponding to the four or more respective wavelength bands.

This imaging system can generate a more accurate hyperspectral image.

### Technique 6

An imaging device including:
an optical filter including regions having different transmittance spectra from each other,
an image sensor that detects light through the optical filter to generate a compressed image in which information regarding four or more wavelength bands is compressed, and
a vibration device that vibrates the image sensor and reduces a spatial frequency component of light incident on the image sensor that is greater than or equal to a specific frequency, and
the specific frequency is less than or equal to 1/(5P) when a pixel pitch of the image sensor is P.

This imaging device can reduce the reconstruction error of a reconstructed image when generating the reconstructed image on the basis of the compressed image.

### Technique 7

The imaging device according to Technique 6,
in which the specific frequency is greater than or equal to 1/(10P).

Regarding light from a target that is incident on the image sensor, this imaging device can suppress the removal of the spatial frequency component of the light that is needed to generate the reconstructed image.

### Technique 8

An imaging system comprising:
the imaging device according to Technique 6 or 7; and
a processing circuit that generates, based on the compressed image, four or more images corresponding to the four or more respective wavelength bands.

This imaging system can generate a more accurate hyperspectral image.

### Technique 9

An imaging system including:
an imaging device, and
a processing circuit, in which
the imaging device includes
   an optical system,
   an optical filter including regions having different transmittance spectra from each other, and
   an image sensor that detects light through the optical system and the optical filter to generate a compressed image in which information regarding four or more wavelength bands is compressed, in which
   the processing circuit
      causes the image sensor to generate compressed images under respective conditions in which a focus position of the optical system differs,
      determines, based on the compressed images, a first condition under which the focus position of the optical system is at its in-focus position,
      causes the image sensor to generate a compressed image under a second condition different from the first condition, and
      generates, based on the compressed image generated under the second condition, four or more images corresponding to the four or more respective wavelength bands.

This imaging system can reduce the reconstruction error of a reconstructed image when generating the reconstructed image on the basis of the compressed image.

### Technique 10

The imaging system according to Technique 9,
in which the second condition is that a spatial frequency component of light incident on the image sensor that is greater than or equal to a specific frequency be reduced, and the specific frequency is less than or equal to 1/(5P) when a pixel pitch of the image sensor is P.

This imaging system can generate a more accurate hyperspectral image.

### Technique 11

The imaging system according to Technique 9 or 10, in which the optical system includes one or more lenses, the one or more lenses include a first lens, and among the one or more lenses, the first lens is the closest to the image sensor, and under the second condition, a distance between the first lens and a light receiving surface of the image sensor is different from a back focus of the optical system.

Regarding light incident on the image sensor, this imaging system can reduce a spatial frequency component of the light that is greater than or equal to a specific frequency by shifting the focus position of the optical system from its in-focus position.

### Technique 12

The imaging system according to any one of Techniques 9 to 11, in which
the processing circuit
   determines whether to operate in a first mode in which a compressed image is displayed without displaying the four or more images or a second mode in which the four or more images are displayed,
   in a case where it is determined to operate in the first mode, causes a display device to display a compressed image generated under the first condition, and
   in a case where it is determined to operate in the second mode, causes the display device to display the four or more images, an analysis result based on the four or more images, or the four or more images and analysis result.

This imaging system can select between the through-display mode and the spectral display mode.

### Technique 13

The imaging system according to Technique 12,
in which the processing circuit determines whether to operate in the first mode or the second mode, based on an input via a user interface from the user.

This imaging system allows selection between the through-display mode and the spectral display mode on the basis of an input from the user.

### Technique 14

The imaging system according to Technique 12, in which
the processing circuit
   determines whether or not the compressed image contains a specific target, and
   determines, based on the determination result, whether to operate in the first mode or the second mode.

This imaging system can select the spectral display mode in a case where the compressed image contains a particular target, and the through-display mode otherwise.

### Technique 15

A method performed by an imaging system including an imaging device,
the imaging device including
   an optical system,
   an optical filter including regions having different transmittance spectra from each other, and
   an image sensor that detects light through the optical system and the optical filter to generate a compressed image in which information regarding four or more wavelength bands is compressed,
   the method including:
      causing the image sensor to generate compressed images under respective conditions in which a focus position of the optical system differs,
      determining, based on the compressed images, a first condition under which the focus position of the optical system is at its in-focus position,
      causing the image sensor to generate a compressed image under a second condition different from the first condition, and
      generating, based on the compressed image generated under the second condition, four or more images corresponding to the four or more respective wavelength bands.

This method makes it possible to reduce the reconstruction error of a reconstructed image when generating the reconstructed image on the basis of the compressed image.

The technology according to the present disclosure is useful, for example, in cameras and measurement devices that acquire multi-wavelength or high-resolution images. The technology according to the present disclosure can be applied, for example, to sensing for biological, medical, and cosmetic applications, inspection systems for foreign matter and pesticide residues in food, remote sensing systems, and vehicle-mounted sensing systems.

What is claimed is:

1. An imaging device comprising:
an optical filter including regions having different transmittance spectra from each other;
an optical element; and
an image sensor that detects light through the optical element and the optical filter to generate a compressed image in which information regarding four or more wavelength bands is compressed, wherein
the optical element reduces a spatial frequency component of light incident on the optical element that is greater than or equal to a specific frequency, and
the specific frequency is less than or equal to 1/(5P) when a pixel pitch of the image sensor is P.

2. The imaging device according to claim 1,
wherein the specific frequency is greater than or equal to 1/(10P).

3. The imaging device according to claim 1,
wherein the optical element is positioned between the optical filter and the image sensor.

4. The imaging device according to claim 1,
wherein the optical filter is positioned between the optical element and the image sensor.

5. An imaging system comprising:
the imaging device according to claim 1; and
a processing circuit that generates, based on the compressed image, four or more images corresponding to the four or more respective wavelength bands.

6. An imaging device comprising:
an optical filter including regions having different transmittance spectra from each other;
an image sensor that detects light through the optical filter to generate a compressed image in which information regarding four or more wavelength bands is compressed; and
a vibration device that vibrates the image sensor and reduces a spatial frequency component of light incident on the image sensor that is greater than or equal to a specific frequency,
wherein the specific frequency is less than or equal to 1/(5P) when a pixel pitch of the image sensor is P.

7. The imaging device according to claim 6,
wherein the specific frequency is greater than or equal to 1/(10P).

8. An imaging system comprising:
the imaging device according to claim 6; and
a processing circuit that generates, based on the compressed image, four or more images corresponding to the four or more respective wavelength bands.

9. An imaging system comprising:
an imaging device; and
a processing circuit, wherein
the imaging device includes
an optical system,
an optical filter including regions having different transmittance spectra from each other, and
an image sensor that detects light through the optical system and the optical filter to generate a compressed image in which information regarding four or more wavelength bands is compressed, wherein
the processing circuit
causes the image sensor to generate compressed images under respective conditions in which a focus position of the optical system differs,
determines, based on the compressed images, a first condition under which the focus position of the optical system is at its in-focus position,
causes the image sensor to generate a compressed image under a second condition different from the first condition, and
generates, based on the compressed image generated under the second condition, four or more images corresponding to the four or more respective wavelength bands.

10. The imaging system according to claim 9,
wherein the second condition is that a spatial frequency component of light incident on the image sensor that is greater than or equal to a specific frequency be reduced, and the specific frequency is less than or equal to 1/(5P) when a pixel pitch of the image sensor is P.

11. The imaging system according to claim 9, wherein
the optical system includes one or more lenses,
the one or more lenses include a first lens, and
among the one or more lenses, the first lens is the closest to the image sensor, and
under the second condition, a distance between the first lens and a light receiving surface of the image sensor is different from a back focus of the optical system.

12. The imaging system according to claim 9, wherein
the processing circuit
determines whether to operate in a first mode in which a compressed image is displayed without displaying the four or more images or a second mode in which the four or more images are displayed,
in a case where it is determined to operate in the first mode, causes a display device to display a compressed image generated under the first condition, and
in a case where it is determined to operate in the second mode, causes the display device to display the four or more images, an analysis result based on the four or more images, or the four or more images and analysis result.

13. The imaging system according to claim 12,
wherein the processing circuit determines whether to operate in the first mode or the second mode, based on an input via a user interface from the user.

14. The imaging system according to claim 12, wherein
the processing circuit
determines whether or not the compressed image contains a specific target, and
determines, based on the determination result, whether to operate in the first mode or the second mode.

15. A method performed by an imaging system including an imaging device,
the imaging device including
an optical system,
an optical filter including regions having different transmittance spectra from each other, and
an image sensor that detects light through the optical system and the optical filter to generate a compressed image in which information regarding four or more wavelength bands is compressed,
the method comprising:
causing the image sensor to generate compressed images under respective conditions in which a focus position of the optical system differs;
determining, based on the compressed images, a first condition under which the focus position of the optical system is at its in-focus position;
causing the image sensor to generate a compressed image under a second condition different from the first condition; and
generating, based on the compressed image generated under the second condition, four or more images corresponding to the four or more respective wavelength bands.
